(19) United States
(12) Patent Application Publication
(10) Pub. No.: US 2017/0025354 A1
(43) Pub. Date: Jan. 26, 2017

(54) Contact Plug Extension for Bit Line Connection

(71) Applicant: SanDisk Technologies, Inc., Plano, TX (US)

(72) Inventors: Shunsuke Watanabe, Yokkaichi (JP); Kiyokazu Shishido, Yokkaichi (JP); Yuji Takahashi, Yokkaichi (JP); Takuya Futase, Yokkaichi (JP); Eiichi Fujikura, Yokkaichi (JP); Noritaka Fukuo, Yokkaichi (JP); Hiroto Ohori, Yokkaichi (JP); Kotaro Jinnouchi, Yokkaichi (JP); Hiroki Asano, Yokkaichi (JP)

(21) Appl. No.: 14/808,966

(22) Filed: Jul. 24, 2015

(51) Int. Cl. H01L 23/535; H01L 23/528; H01L 21/768; H01L 23/532

(52) U.S. Cl. CPC H01L 23/535; H01L 23/53257; H01L 23/5329; H01L 23/5283; H01L 21/76816; H01L 21/76895

(57) ABSTRACT

An integrated circuit connection structure includes a contact plug extending vertically in a first dielectric, a conductive line formed of a metal extending horizontally in the first dielectric, and a contact plug extension that extends between a top surface of the contact plug and the conductive line. The plug extension is formed of the metal, has a bottom surface that lies in contact with the top surface of the contact plug, and is bounded on at least one side by a portion of a second dielectric material.

### BACKGROUND

This application relates generally to non-volatile semiconductor memories of the flash memory type, their formation, structure and use.

There are many commercially successful non-volatile memory products being used today, particularly in the form of small form factor cards, USB drives, embedded memory, and Solid State Drives (SSDs) which use an array of flash EEPROM cells. An example of a flash memory system is shown in FIG. 1, in which a memory cell array 1 is formed on a memory chip 12, along with various peripheral circuits such as column control circuits 2, row control circuits 3, data input/output circuits 6, etc.

One popular flash EEPROM architecture utilizes a NAND array, wherein a large number of strings of memory cells are connected through one or more select transistors between individual bit lines and a reference potential. A portion of such an array is shown in plan view in FIG. 2A. Although four floating gate memory cells are shown in each string, the individual strings typically include 16, 32 or more memory cell charge storage elements, such as floating gates, in a column. Control gate (word) lines labeled WL0-WL3 and string selection lines, Drain Select Line, “DSL” and Source Select Line “SSL” extend across multiple strings over rows of floating gates. An individual cell within a column is read and verified during programming by causing the remaining cells in the string to be turned on hard by placing a relatively high voltage on their respective word lines and by placing a relatively lower voltage on the one selected word line so that the current flowing through each string is primarily dependent only upon the level of charge stored in the addressed cell below the selected word line. That current typically is sensed for a large number of strings in parallel, thereby to read charge level states along a row of floating gates in parallel.

The top and bottom of the string connect to the bit line and a common source line respectively through select transistors (source select transistor and drain select transistor). Select transistors do not contain floating gates and are used to connect NAND strings to control circuits when they are to be accessed, and to isolate them when they are not being accessed.

NAND strings are generally connected by conductive lines in order to form arrays that may contain many NAND strings. At either end of a NAND string a contact area may be formed. This allows connection of the NAND string as part of the array. Metal contact plugs (or “vias”) may be formed over contact areas to connect the contact areas (and thereby connect NAND strings) to conductive metal lines that extend over the memory array (e.g. bit lines). FIG. 2A shows bit line contacts BL0-BL4 and common source line contacts at either end of NAND strings. Contacts to contact areas may be formed by etching contact holes through a dielectric layer and then filling the holes with metal to form contact plugs. Metal lines, such as bit lines, extend over the memory array and in peripheral areas in order to connect the memory array and various peripheral circuits. Electrical contact between metal lines and contact plugs occurs where horizontal metal lines intersect vertical contact plugs. These metal lines may be close together which tends to make processing difficult and provides a risk of shorting or current leakage, especially where there is some misalignment between bit lines and contact plugs. The quality of connections with contact plugs may be a significant factor for good memory operation because of leakage currents, resistance, capacitive coupling, and other related problems.

Thus, there is a need for structures and methods that allow misaligned bit line-to-contact plug connections to be formed without significant shorting or leakage current and with acceptable contact resistance.

### SUMMARY

According to an example of formation of a memory integrated circuit, leakage current between a contact plug and an adjacent bit line (adjacent to the bit line the contact plug contacts) is substantially prevented by ensuring that a portion of dielectric remains between the contact plug and the adjacent bit line, and that it is of a suitable material and has suitable dimensions to prevent substantial leakage. Contact plugs may be etched back so that top surfaces of contact plugs are further from bottom surfaces of bit lines. Such etching back forms recessed spaces over contact plugs. A contact plug extension may be formed in such a recessed space and may connect a contact plug to a corresponding bit line. The plug extension may be constrained to the recessed space over its designated contact plug which is self-aligned with the contact plug and may be further constrained to an area underlying a corresponding bit line (i.e. a plug extension is only formed where a bit line overlies a contact plug. Such a constrained plug extension remains relatively far from neighboring contact plugs and thus does not provide a ready pathway for leakage current with neighboring contact plugs. Etching back of contact plugs may occur after bit line trenches are etched, or earlier, before bit line trenches or the dielectric in which they are etched are formed. Upper surfaces of contact plugs may be shaped to provide increased surface area for bit line metal contact. Where contact plugs have a central seam and smaller grain size closer to the seam, over etching may produce a conical depression which increases contact area and lowers contact resistance accordingly.

An example of an integrated circuit connection structure includes: a contact plug extending vertically in a first dielectric; a conductive line formed of a metal extending horizontally in the first dielectric; and a plug extension that extends between a top surface of the contact plug and the conductive line, the plug extension formed of the metal, the plug extension having a bottom surface that lies in contact with the top surface of the contact plug, the plug extension bounded on at least one side by a portion of a second dielectric material.

The top surface of the contact plug may be partially in contact with the bottom surface of the plug extension and may be partially covered by the second dielectric. The top surface of the contact plug may have a first perimeter, the bottom surface of the plug extension may have a second perimeter, the second perimeter having a section that is coextensive with a corresponding section of the first perimeter. The conductive line may overlie the portion of the second dielectric in an area that lies adjacent to the extension plug. The first dielectric may be silicon oxide and the second dielectric may be silicon nitride. The second dielectric material may form a silicon nitride layer that extends between an underlying layer of silicon oxide and an overlying layer of silicon oxide. An adjacent conductive line may extend parallel to the conductive line, the adjacent conductive line having a bottom surface that lies along a top surface of the silicon nitride layer so that silicon nitride extends between the adjacent conductive line and the contact plug. The portion of the second dielectric material may form a collar around the top surface of the contact plug. The collar may extend higher than the top surface of the contact plug and may connect a bottom surface of the conductive line. The portion of the second dielectric material may occupy an area of the top surface of the contact plug that is not occupied by the plug extension. The portion of the second dielectric material and the plug extension together may occupy the entire area of the top surface of the contact plug. The bottom surface of the plug extension may lie in contact with the top surface of the contact plug along an interface that is substantially conical in shape. The interface may be substantially defined by an inverted conical surface that has a taper angle between thirty five degrees (35°) and fifty five degrees (55°).

An example of a method of forming a connection structure includes: forming a contact plug; forming a protective portion of a first dielectric material; forming a layer of a second dielectric material over the contact plug; forming an opening in the layer of the second dielectric material that exposes a portion of a top surface of the contact plug; forming a metal plug extension in the opening, the metal plug extension laterally constrained in at least one direction by the protective portion of the first dielectric material; and forming a plurality of conductive metal lines, a first conductive metal line formed over the metal plug extension and in electrical contact with the metal plug extension, a second conductive metal line adjacent to the first conductive metal line being separated from the contact plug by the protective portion of the first dielectric material.

Forming the opening in the layer of the second dielectric material may include performing anisotropic etching using an etch that is selective to the second dielectric material, having a significantly higher etch rate for the second dielectric material than for the first dielectric material. Subsequent to exposing the portion of the top surface of the contact plug, the portion of the top surface of the contact plug may be etched to thereby form a substantially conical depression in the contact plug. The depression may subsequently be filled by the metal plug extension so that an interface between the metal plug extension and the contact plug is substantially conical in shape with an angle between thirty five degrees (35°) and fifty five degrees (55°). Forming the contact plug may include depositing tungsten (W) by Chemical Vapor Deposition (CVD) thereby forming a seam in a central area of the contact plug, and etching the portion of the top surface of the contact plug may provide a higher etch rate along the seam than in a peripheral area of the top surface of the contact plug. The first dielectric material may be silicon oxide and the second dielectric material may be silicon oxide. The protective portion of the first dielectric material may be formed by depositing a layer of the first dielectric material over a layer of the second dielectric material prior to formation of the contact plug, and the contact plug may subsequently be formed by etching a contact hole through the layer of the first dielectric material and the layer of the second dielectric material and filling the hole with metal. The contact plug may be etched back prior to deposition of the second dielectric material so that the top surface of the contact plug lies lower than a top surface of the layer of the first dielectric material. The protective portion of the first dielectric material may be formed by, subsequent to forming the opening in the layer of the second dielectric material: selectively etching back the contact plug to form a plug-shaped space; filling the plug-shaped space with the first dielectric material; and subsequently, performing anisotropic selective etching to remove exposed first dielectric material from the opening, while leaving the protective portion of the first dielectric material in a portion of the plug-shaped space that is not exposed. The protective portion of the first dielectric material may be formed by: subsequent to forming the contact plug, etching back the contact plug; subsequently, etching back dielectric around the contact plug, using isotropic etching, to form a recess around the top surface of the contact plug; subsequently, depositing the first dielectric material; and subsequently etching back the first dielectric material to expose at least a central portion of the top surface of the contact plug while leaving the first dielectric material in the recess. The protective portion may form a ring that encircles the top surface of the contact plug and may partially overlie the top surface of the contact plug near a perimeter of the top surface of the contact plug.

An example of a method of forming a connection structure includes: forming a contact plug; subsequently recessing a top surface of the contact plug; forming a protective portion of a first dielectric material in a recessed space adjacent to the top surface of the contact plug; subsequently exposing a contact area of the recessed top surface of the contact plug using selective anisotropic etching; and depositing metal to form a plurality of conductive lines, the metal lying in contact with the contact area of the recessed top surface of the contact plug under a first conductive line, a second conductive line separated from the contact plug by the protective portion of the first dielectric material.

The method may also include, subsequent to recessing the top surface of the contact plug: etching isotropically to form an annular recess about the top surface of the contact plug; and forming the protective portion in the annular recess, the protective portion circumscribing the top surface of the contact plug and partially overlying the top surface of the contact plug. Recessing the top surface of the contact plug may leave the recessed space having a plug-shape extending over the top surface of the contact plug, and further comprising: filling the recessed space with the first dielectric to form a dielectric plug; and subsequently etching away part of the dielectric plug overlying the contact area to thereby expose the contact area of the recessed top surface of the contact plug while a remaining part of the dielectric plug forms the protective portion on an unexposed area of the top surface of the contact plug.

Various aspects, advantages, features and embodiments are included in the following description of examples, which description should be taken in conjunction with the accompanying drawings.

### BRIEF DESCRIPTION OF THE DRAWINGS

FIG. 1 is a block diagram of a prior art memory system.

FIG. 2A is a plan view of a prior art NAND array.

FIG. 2B shows a cross section of the NAND array of FIG. 2A.

FIG. 2C shows another cross section of the NAND array of FIG. 2A.

FIG. 3 illustrates an example of formation of air gaps between bit lines.

FIG. 4 shows a cross section of a portion of a NAND memory die where bit lines connect to contact plugs at an intermediate stage of fabrication.

FIG. 5 shows an alternative structure with a larger distance between a contact plug and neighboring bit line.

FIG. 6 shows bit line trenches that are misaligned with contact plugs.

FIG. 7 shows the structure of FIG. 6 after selective etching back of the contact plug.

FIG. 8 shows the structure of FIG. 7 after deposition of a second dielectric material.

FIG. 9 shows the structure of FIG. 8 after etching to expose a portion of the top surface of the contact plug.

FIG. 10 shows the structure of FIG. 9 after deposition of bit line metal.

FIG. 11 shows another example of a dielectric portion that maintains a distance between a contact plug and a neighboring bit line.

FIG. 12 shows contact plugs in a silicon oxide layer.

FIG. 13 shows the structure of FIG. 12 with contact plugs etched back.

FIG. 14 shows the structure of FIG. 13 during isotropic etching of silicon oxide.

FIG. 15 shows the structure of FIG. 14 after deposition of silicon nitride.

FIGS. 16A-B show the structure of FIG. 15 after etching back to leave silicon nitride collars around upper surfaces of contact plugs.

FIG. 17 shows an example of contact plugs extending through a silicon nitride layer and a silicon oxide layer.

FIG. 18 shows the structure of FIG. 17 after etching back of contact plugs.

FIG. 19 shows the structure of FIG. 18 after deposition of silicon oxide.

FIG. 20 shows the structure of FIG. 19 after planarization.

FIG. 21 shows the structure of FIG. 20 after deposition of a silicon oxide layer and formation of bit line trenches in the silicon oxide layer.

FIG. 22 shows bit lines formed in bit line trenches and contact plug extensions.

FIG. 23 illustrates contact plugs with shaped upper surfaces.

FIG. 24 shows filling of contact holes at a first stage.

FIG. 25 shows filling of contact holes at a later stage when a seam is formed.

FIG. 26 shows tungsten of different grain size formed at different stages of contact hole filling.

FIG. 27 illustrates etching of a contact plug that has a seam and varied grain size.

FIGS. 28A-B illustrate a planar interface between bit line metal and a contact plug.

FIGS. 29A-B illustrate a conical interface between bit line metal and a contact plug.

FIG. 30 illustrates an example of process steps used to form contact plugs and bit lines.

### DETAILED DESCRIPTION OF EXEMPLARY EMBODIMENTS

### Memory System

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and magnetoresistive random access memory (“MRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Then again, two dimensional arrays may be formed separately and then packaged together to form, a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

In other embodiments, types of memory other than the two dimensional and three dimensional exemplary structures described here may be used.

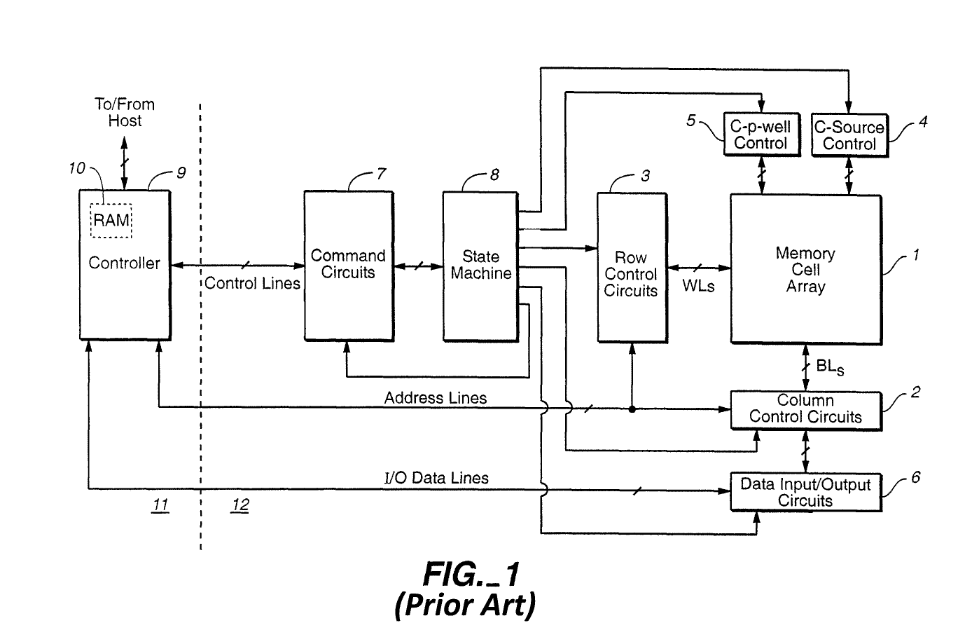

An example of a prior art memory system, which may be modified to include various structures described here, is illustrated by the block diagram of FIG. 1. A planar memory cell array 1 including a plurality of memory cells is controlled by a column control circuit 2, a row control circuit 3, a c-source control circuit 4 and a c-p-well control circuit 5. The memory cell array 1 is, in this example, of the NAND type similar to that described above in the Background and in references incorporated therein by reference. A control circuit 2 is connected to bit lines (BL) of the memory cell array 1 for reading data stored in the memory cells, for determining a state of the memory cells during a program operation, and for controlling potential levels of the bit lines (BL) to promote the programming or to inhibit the programming. The row control circuit 3 is connected to word lines (WL) to select one of the word lines (WL), to apply read voltages, to apply program voltages combined with the bit line potential levels controlled by the column control circuit 2, and to apply an erase voltage coupled with a voltage of a p-type region on which the memory cells are formed. The c-source control circuit 4 controls a common source line (labeled as “c-source” in FIG. 1) connected to the memory cells (M). The c-p-well control circuit 5 controls the c-p-well voltage.

The data stored in the memory cells are read out by the column control circuit 2 and are output to external I/O lines via an I/O line and a data input/output buffer 6. Program data to be stored in the memory cells are input to the data input/output buffer 6 via the external I/O lines, and transferred to the column control circuit 2. The external I/O lines are connected to a controller 9. The controller 9 includes various types of registers and other memory including a volatile random-access-memory (RAM) 10.

The memory system of FIG. 1 may be embedded as part of the host system, or may be included in a memory card, USB drive, or similar unit that is removably insertable into a mating socket of a host system. Such a card may include the entire memory system, or the controller and memory array, with associated peripheral circuits, may be provided in separate cards. The memory system of FIG. 1 may also be used in a Solid State Drive (SSD) or similar unit that provides mass data storage in a tablet, laptop computer, or similar device. Memory systems may be used with a variety of hosts in a variety of different environments. For example, a host may be a mobile device such as a cell phone, laptop, music player (e.g. MP3 player), Global Positioning System (GPS) device, tablet computer, or the like. Such memory systems may be inactive, without power, for long periods during which they may be subject to various conditions including high temperatures, vibration, electromagnetic fields, etc. Memory systems for such hosts, whether removable or embedded, may be selected for low power consumption, high data retention, and reliability in a wide range of environmental conditions (e.g. a wide temperature range). Other hosts may be stationary. For example, servers used for internet applications may use nonvolatile memory systems for storage of data that is sent and received over the internet. Such systems may remain powered up without interruption for extended periods (e.g. a year or more) and may be frequently accessed throughout such periods. Individual blocks may be frequently written and erased so that endurance may be a major concern.

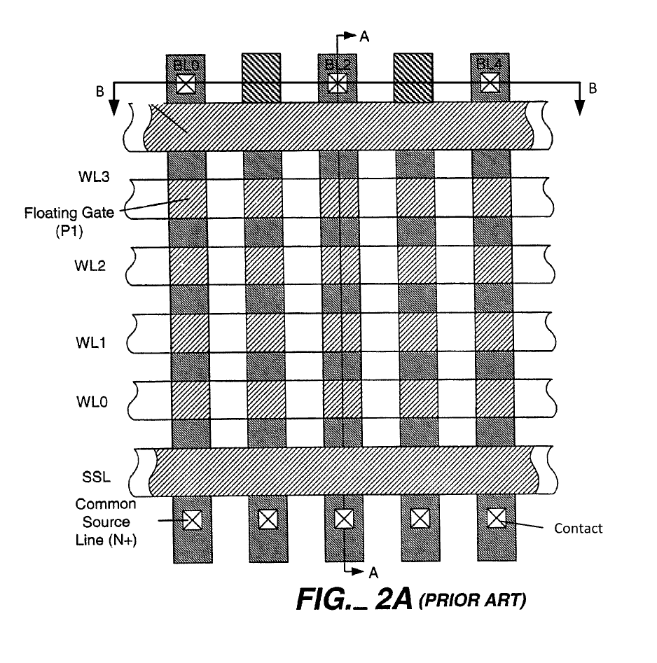

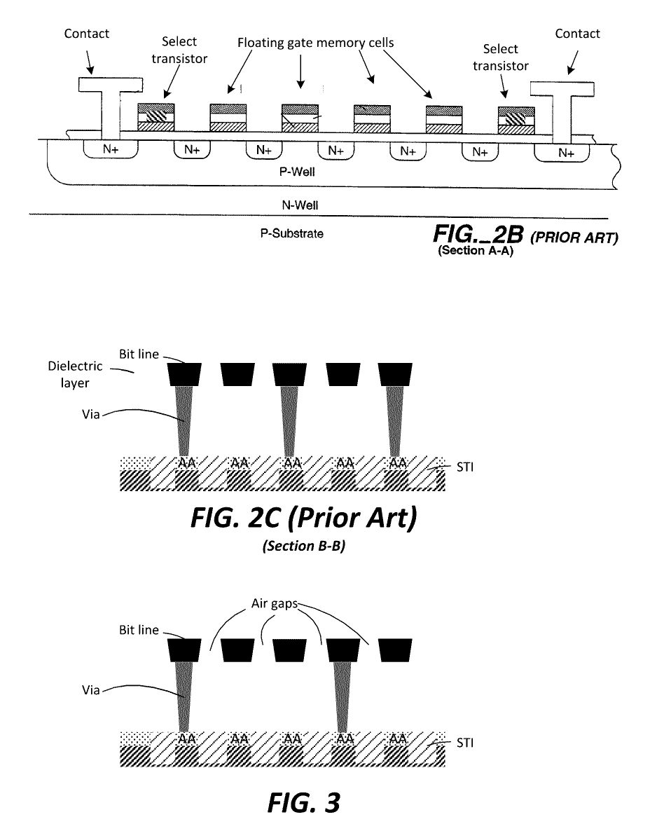

FIGS. 2A-2C show different views of a prior art NAND flash memory. In particular, FIG. 2A shows a plan view of a portion of such a memory array including bit lines and word lines (this is a simplified structure with a small number of word lines and bit lines). FIG. 2B shows a cross section along A-A (along a NAND string) showing individual memory cells that are connected in series. Contact plugs, or vias, are formed at either end to connect the NAND strings in the memory array to conductive lines (e.g. connecting to bit lines at one end and to a common source line at the other end). Such a contact plug may be formed of metal that is deposited into a contact hole that is formed in a dielectric layer. FIG. 2C shows a cross section along B-B of FIG. 2A. This view shows metal contact plugs extending down through contact holes in a dielectric layer to make contact with active areas (“AA”) in the substrate (i.e. with N+ areas of FIG. 2B). STI regions are located between active areas of different strings to electrically isolate an individual NAND string from its neighbors. Bit lines extend over the memory array in a direction perpendicular to the cross section shown. Alternating bit lines are connected to vias in the cross section shown. (It will be understood that other vias, that are not visible in the cross section shown, connect the remaining bit lines to other active areas). In this arrangement, locations of vias alternate so that there is more space between vias and thus less risk of contact between vias. Other arrangements are also possible.

As memories become smaller, the spacing between bit lines tends to diminish. Accordingly, capacitive coupling between bit lines tends to increase as technology progresses to ever-smaller dimensions. FIG. 2C shows an example of bit lines formed in a dielectric material. For example, copper bit lines may be formed by a damascene process in which elongated openings, or trenches, are formed in the dielectric layer and then copper is deposited to fill the trenches. When excess copper is removed (e.g. by Chemical Mechanical Polishing, CMP) copper lines remain. A suitable dielectric may be chosen to keep bit line-to-bit line capacitance low.

One way to reduce bit line-to-bit line coupling is to provide an air gap between neighboring bit lines. Thus, rather than maintain dielectric portions between bit lines, the bit lines are formed in a sacrificial layer which is then removed to leave air gaps between bit lines. FIG. 3 shows a simplified illustration of bit lines that are separated by air gaps.

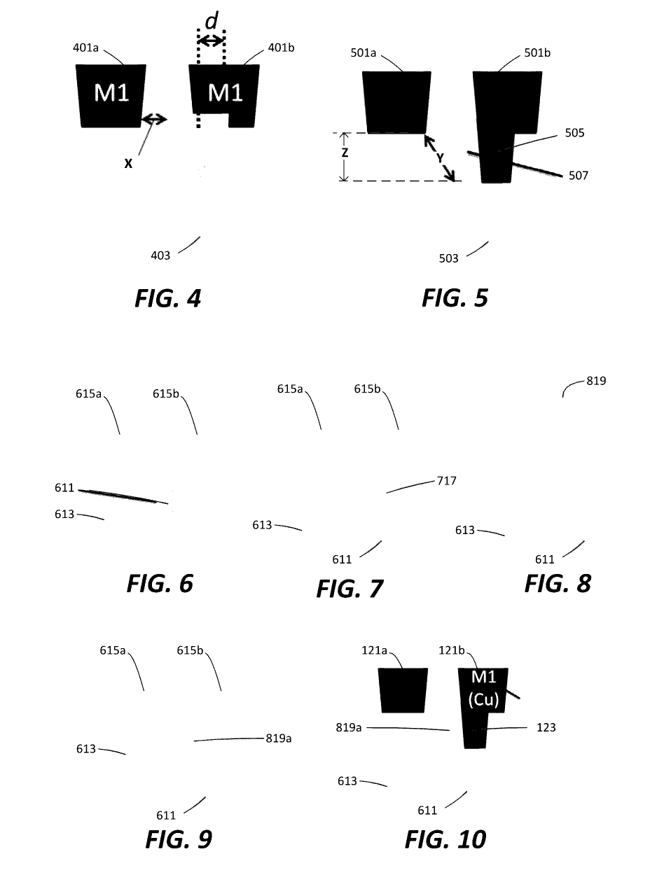

As memories become smaller, alignment errors may have more significant effects. FIG. 4 illustrates an example where bit lines 401a-b formed of a metal layer (“M1” layer) are misaligned with an underlying contact plug 403 (“V1” via layer) by a distance “d.” It can be seen that this results in a reduced distance, X, between a contact plug and a neighboring (or adjacent) bit line 401a (i.e. a bit line that is adjacent to bit line 401b that the contact plug is designed to connect with). In larger memories such a reduced distance may not be problematic because there is still sufficient distance to prevent current leakage, i.e. X may be sufficient to insulate contact plug 403 from neighboring bit line 401a. However, as dimensions become smaller there may be little tolerance for reducing such a dimension because the designed distance may be close to the minimum distance needed to avoid significant leakage. Providing more precise alignment may be possible in some cases but may add cost.

Contact Plug Extension

FIG. 5 shows an example of a pattern of bit lines 501a-b that are similarly misaligned with contact plug 503. However, in this example, the distance, Y, between contact plug 503 and the neighboring bit line 501a remains relatively wide compared with the example of FIG. 4 (i.e. Y>X). In particular, there is a vertical offset, Z, between the top of contact plug 503 and the bottom of the bit lines 501a-b that ensures a relatively large distance between contact plug 503 and neighboring bit line 501a even when there is significant lateral misalignment. In order to connect contact plug 503 and the bit line 501b that it is designed to connect, a plug extension 505 extends down from bit line 501b to contact the upper surface of contact plug 503. The plug extension 505 does not extend towards neighboring bit line 501a and thus does not provide a likely pathway for current leakage, i.e. plug extension 505 does not have the same profile as a contact plug. In particular, a portion of dielectric material 507 is formed over the upper surface of contact plug 503 and along a side of the plug extension 505 and the plug extension does not extend laterally from under bit line 501b (i.e. remains within the footprint of the bit line).

While the via and bit lines are formed in layers of a first dielectric material (e.g. silicon oxide) in this example, the portion of dielectric 507 is formed of a second dielectric material (e.g. silicon nitride) in order to facilitate fabrication. The structure of FIG. 5 may be formed in any suitable manner. An example of steps that may be used to form such a structure are provided in FIGS. 6-10.

FIG. 6 shows an example of a contact plug 611 in silicon oxide 613 after etching trenches in which bit lines are to be formed (bit line trenches 615a-b). It can be seen that there is some misalignment of the bit line pattern so that a relatively small distance separates contact plug 611 from bit line trench 615a. However, instead of immediately filling trenches with bit line material to form bit lines, further process steps are performed to provide adequate distance between contact plug 611 and a neighboring bit line.

FIG. 7 shows the result of a selective etch step that etches back the contact plug 611 to a level that provides sufficient distance between the contact plug and subsequently formed bit lines. The etch step may use isotropic etching (e.g. wet etching) that is selective to contact plug material (e.g. tungsten) while leaving silicon oxide 613 substantially unetched. An example of a suitable etch may use hydrogen peroxide (H₂O₂) to etch tungsten and ammonia peroxide mixture (APM) to etch barrier layer titanium nitride (TiN). (It will be understood that bit lines may be formed of various metals or combinations of metals either with or without barrier layers or other additional layers.) Other etches may be used as appropriate for other materials. This etch step creates a recessed space 717 that is plug-shaped as a result of being formed by removal of part of the contact plug. Thus, the recessed space 717 is self-aligned with contact plug 611.

FIG. 8 shows the result of a subsequent deposition step in which a second dielectric material 819, in this case silicon nitride (SiN), is deposited to fill trenches 615a-b and to fill recessed space 717. A suitable deposition technique may be used to ensure good filling of trenches and spaces, e.g. atomic layer deposition (ALD) or other high step-coverage process may be used.

FIG. 9 shows the result of subsequent selective anisotropic etching of second dielectric material 819. Reactive ion etching (RIE) may be used to selectively remove silicon nitride without substantially etching silicon oxide 613. Etching extends down to the upper surface of contact plug 611, thereby exposing part of the upper surface of contact plug 611, while maintaining silicon nitride portion 819a that is not exposed under trench 615b. Thus, etching proceeds under trench 615b but does not extend laterally towards neighboring bit line 615a. Etching is also limited to the space above contact plug 611 by silicon oxide 613. Thus, etching is confined to an area where bit line trench 615b overlies contact plug 611.

FIG. 10 shows the result of depositing barrier layer metal (e.g. titanium, Ti, or titanium nitride, TiN) and bit line metal (e.g. copper, Cu) to fill trenches 615a-b and subsequent planarization to remove excess material. Bit lines 121a-b are thus formed in the trenches 615a-b and a contact plug extension 123 is formed extending down from bit line 121b to connect bit line 121b with contact plug 611. Silicon nitride portion 819a remains in place to provide insulation that prevents significant current leakage between neighboring bit line 121a and contact plug 611 or contact plug extension 123. The upper surface of contact plug 611 is partially covered by silicon nitride portion 819a and the rest of the upper surface is covered by plug extension 123. Because contact plug extension 123 and silicon nitride portion 819a are formed in recessed space 717, they remain within a perimeter defined by contact plug 611, i.e. bottom surfaces of plug extension 123 and silicon nitride portion 819a have a perimeter that is coextensive with the perimeter of the upper surface of contact plug 611.

### Dielectric Collar

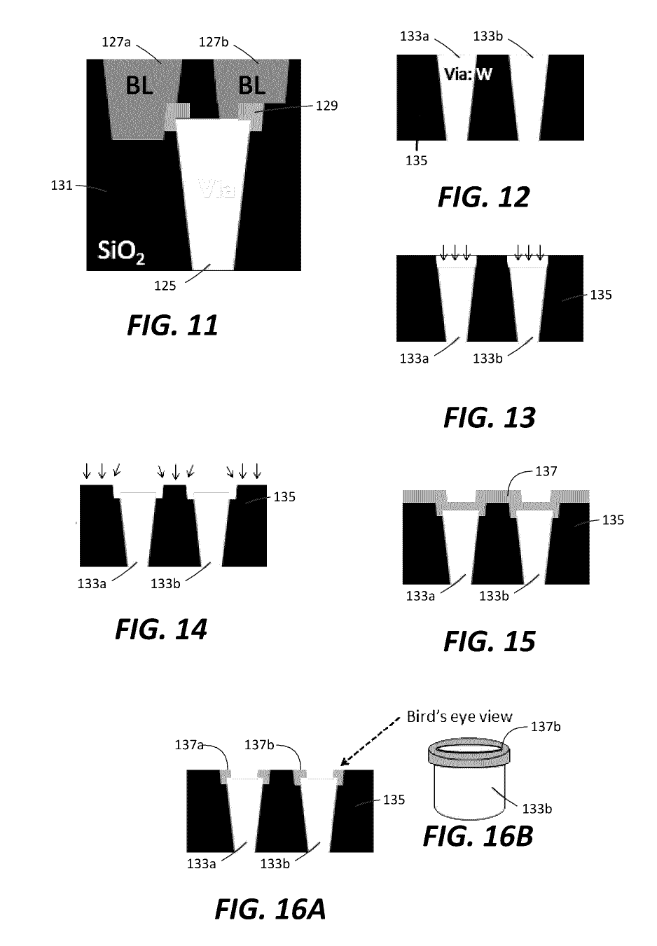

Another example of providing sufficient dielectric between a contact plug 125 and a neighboring bit line 127a is illustrated in FIG. 11. In this case, a portion of dielectric forms a collar 129 around the upper surface of contact plug 125. A collar may be of a suitable material (e.g. silicon nitride) and of suitable dimensions to maintain leakage currents below a specified limit (e.g. ensuring five nanometers (5 nm) of dielectric such as silicon nitride between a contact plug and neighboring bit line). In particular, the collar may be formed of a different dielectric to the dielectric material in which the contact plug and bit lines are formed (e.g. silicon oxide 131) so that selective etching may be used to form bit line trenches. Such selective etching forms bit line trenches that expose top surfaces of contact plugs while leaving dielectric collars in place so that some minimum distance is maintained with neighboring bit lines. Subsequent deposition forms plug extensions that are limited by dielectric collars and thus maintain a minimum distance from neighboring contact plugs.

An example of process steps for forming a dielectric collar is illustrated in FIGS. 12-17. However, any suitable process may be used to form such a collar.

FIG. 12 shows formation of contact plugs 133a-b of tungsten (W) in a dielectric layer 135 (silicon oxide, SiO2 in this example). The upper surface is planarized so that any excess tungsten is removed and the tops of contact plugs 133a-b are flush with the upper surface of dielectric layer 135.

FIG. 13 shows etching back of tungsten contact plugs 133a-b using a selective etch that does not substantially etch the dielectric layer 135. For example, contact plugs may be etched back about ten nanometers (10 nm). In some cases processing may alternate between planarization and etching back so that these steps are performed more than once.

FIG. 14 illustrates a subsequent etch step in which isotropic etching (e.g. wet etching) is used to selectively etch silicon oxide 135 without substantially etching contact plugs 133a-b. For example, dilute hydrofluoric acid (DHF) or chemical dry etching (CDE) may be used to selectively isotropically etch silicon oxide. Such etching lowers the upper surface of the dielectric layer 135 and expands the side surfaces of dielectric where they were exposed by etching back contact plugs 133a-b. This forms annular (ring-shaped) depressions around the tops of contact plugs as shown. In some examples, this step may not be necessary because the ring-shaped depressions may not be needed.

FIG. 15 shows subsequent deposition of a second dielectric material 137, such as silicon nitride (SiN). For example, approximately two to five nanometers (2-5 nm) of silicon nitride may be deposited to cover the dielectric layer 135 and contact plugs 133a-b.

FIG. 16A shows the result of etching back silicon nitride 137 (e.g. using RIE) so that silicon nitride is removed from horizontal upper surfaces of the dielectric layer 135 and contact plugs 133a-b leaving collars 137a-b of silicon nitride around upper surfaces of contact plugs. FIG. 16B illustrates collar 137b and contact plug 133b in perspective (“bird's eye views”) with collar 137b extending as a ring of dielectric material. While collar 137b extends partially over the upper surface of the contact plug, a substantial portion of the upper surface may be exposed so that sufficient contact area is provided to maintain an acceptable contact resistance. If etching of FIG. 14 is not performed then substantially all of the silicon nitride collar may be located on an upper surface of a contact plug and may not extend down around a side surface of the contact plug. In some cases, collars may extend a significant distance between contact plugs and may leave little or no space between neighboring collars, e.g. neighboring collars may connect.

Subsequent to the formation of collars 137a-b shown in FIGS. 16A-B, an overlying dielectric layer (e.g. silicon oxide) may be formed, and bit line trenches may be formed in the dielectric using an etch that is selective to silicon oxide and does not substantially etch silicon nitride. When misalignment results in trenches intersecting silicon nitride collars, the silicon nitride collars remain in place and thus provide insulation between contact plugs and neighboring bit lines as shown in FIG. 11.

### Protective Dielectric Layer

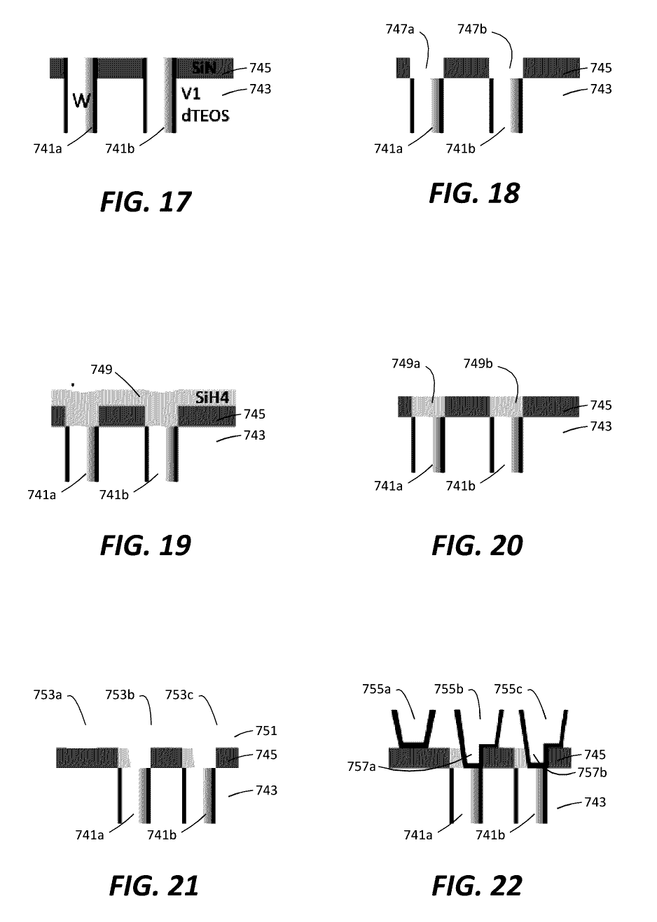

An alternative form of protection between a contact plug and an adjacent bit line may be provided by a protective dielectric layer. FIGS. 17-22 illustrate how such a layer may be formed. Such a layer may allow misalignment of bit lines with contact plugs without significant leakage current.

FIG. 17 shows an example of tungsten contact plugs 741a-b that extend through two dielectric layers, a lower dielectric layer 743 formed of silicon oxide (e.g. formed by tetraethyl orthosilicate, “TEOS”) and an upper dielectric layer 745 that is formed of silicon nitride (SiN). First and second dielectric layers 743, 745 may be deposited and then etched together to form contact holes that are filled with tungsten and a barrier layer such as nitride metal (e.g. titanium nitride, TiN), then planarized (e.g. by chemical mechanical polishing, CMP) to leave contact plugs 741a-b as shown.

FIG. 18 shows the structure of FIG. 17 after subsequent selective etching back of tungsten contact plugs 741a-b. For example, a wet etch using DHF, hydrogen peroxide, or other suitable solution may be used to etch back contact plugs 741a-b without substantially etching silicon nitride layer 745. In the example shown, contact plugs 741a-b are etched down to approximately the same level as the interface between dielectric layers 743, 745. Plug-shaped recesses 747a-b are formed by this etching.

FIG. 19 shows the structure of FIG. 18 after deposition of a dielectric material 749 to fill recesses 747a-b. Dielectric material also overlies the silicon nitride layer 745. A suitable dielectric material may be SiO2 or SiH4.

FIG. 20 shows the structure of FIG. 19 after planarization, e.g. by CMP or etching back. This step removes excess dielectric material from over the silicon nitride layer 745 leaving portions 749a-b of the dielectric material only at locations over upper surfaces of contact plugs 741a-b.

FIG. 21 shows the structure of FIG. 20 after subsequent deposition of another dielectric layer 751 (e.g. silicon oxide) over the silicon nitride layer 745 and formation of bit line trenches 753a-c in dielectric layer 751. It can be seen that bit line trenches 753a-c are misaligned with contact plugs 741a-b. However, by using an etch that is selective to silicon oxide, and has a low etch rate for silicon nitride, this etch step does not significantly etch silicon nitride layer 745. Wherever the silicon nitride layer is encountered, the silicon nitride remains. Thus, the silicon nitride layer 745 acts as an etch-stop layer that may provide uniformity of bit line thickness. Openings in the silicon nitride layer over the contact plugs confine further etching to the area over the contact plugs and anisotropic etching effectively confines etching to the trench pattern. Thus, the upper surfaces of contact plugs 741a-b are exposed while the silicon nitride layer 745 provides separation from neighboring bit line trenches. Silicon nitride layer 745 may be considered a multi-purpose layer because it acts as an etch stop layer when etching bit line trenches, as a masking layer that confines further etching to locations over contact holes, and as a dielectric layer between contact plugs and neighboring bit lines.

FIG. 22 shows the results of depositing a barrier layer and bit line metal (e.g. titanium nitride and copper) on the structure of FIG. 21 to form bit lines 755a-c. It can be seen that contact plug extensions 757a-b extend from the bit lines 755b-c down to upper surfaces of contact plugs 741a-b. Portions of silicon nitride layer 745 separate contact plugs 741a-b from adjacent bit lines.

### Interface Geometry

As memory integrated circuits become smaller, contact areas tend to become smaller. For example, the contact area where bit line metal contacts a contact plug diminishes as both contact plug diameter and bit line width get smaller. As contact area gets smaller, contact resistance increases accordingly. Such contact resistance may become significant in some small structures. Contact plug geometry may be modified to provide a larger contact area and may thereby reduce contact resistance.

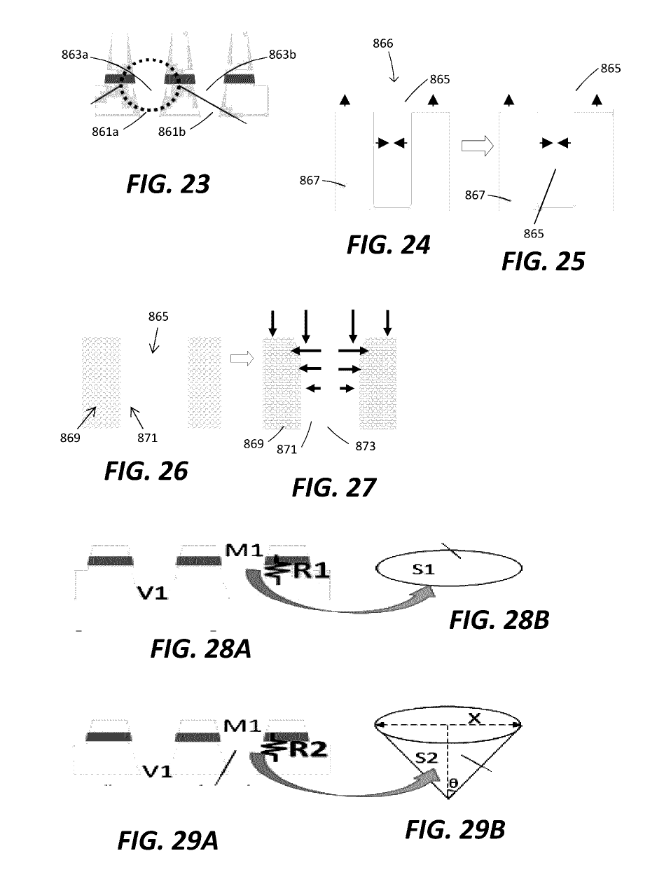

FIG. 23 shows a cross section of contact plugs 861a-b with upper surfaces that are configured to provide a large area of contact between bit line metal and contact plugs. Contact plugs 861a-b have depressions 863a-b formed that are substantially conical in shape (v-shaped in cross section). When bit line metal is deposited, the increase in surface area provides a corresponding reduction in contact resistance compared with a planar interface.

A non-planar geometry such as the conical geometry of FIG. 23 may be achieved in any suitable manner. FIGS. 24-27 illustrate some steps in forming contact plugs with conical depressions in their upper surfaces according to an example.

FIG. 24 shows formation of a contact plug by CVD deposition of tungsten 865 in a contact hole 866 in a dielectric layer 867. Tungsten deposition occurs along all exposed surfaces including sides of contact hole 866 and top surfaces of the dielectric layer 867.

FIG. 25 shows contact hole 866 being filled as tungsten 865 deposited on opposing sides approach a middle line of the contact hole. A seam is formed where material from opposing sides meets, i.e. there is some discontinuity in any grain structure where material meets so that a seam exists. Some voids may be present also.

Also, as the contact hole becomes nearly full, grain size tends to diminish because the remaining space does not allow large grains to form. FIG. 26 illustrates growth on two sidewalls of a contact hole 865 with relatively large grain size tungsten 869 closer to sidewalls and smaller grain size tungsten 871 closer to a middle line of the contact hole.

FIG. 27 illustrates etching the structure of FIG. 26. Anisotropic etching (e.g. RIE) is directed downwards. However, etch rates are higher in small grain size tungsten 871 near seam 873 than in larger grain size tungsten 869 that is farther from seam 873. This leads to etching that produces a substantially conical surface. Thus, by selecting an appropriate tungsten deposition technique, subsequent tungsten etch rates may vary from the center to the edge of a contact plug and the upper surface of the contact plug may be shaped accordingly. For example, when etching to expose the upper surface of the contact plug prior to deposition of bit line metal, the upper surface may first be exposed and may then be further etched (over etched) to form depressions in the upper surface. The same etch conditions used to form the bit line trenches may be used for etching the upper surface, i.e. etching just continues for longer—overetching the bit line trenches after contact plugs are already exposed.

FIG. 28A-B illustrate geometry of a conventional bit line metal, M1, to contact plug, V1, interface in which interface area S1 is simply the area of the disk illustrated in FIG. 28B, i.e. m*r². The contact resistance of the interface R1 is inversely proportional to area S1.

In contrast, FIGS. 29A-B illustrate geometry of bit line metal, M1, to contact plug, V1, interface where the upper surface of the contact plug has a conical depression formed prior to deposition of bit line metal. A cone, with angle (angle of taper) θ, has a contact area S2 that is π*r²/Sin θ. Thus, the ratio of S2/S1 is 1/Sin θ and the ratio of R2/R1 is Sin θ. For example, if θ is forty five degrees (45°) then R2 is about 0.7*R1. This represents a reduction in contact resistance of about thirty percent (30%). A conical depression with an angle of about forty five degrees (45°), e.g. between thirty five and fifty five degrees (35°<θ<55°) may thus provide a significant improvement in contact resistance. Other shapes that similarly increase interface area may similarly reduce contact resistance. Such contact plug shaping may be applied to any contact plug including a contact plug that is contacted by a contact plug extension according to one of the above examples. Such a contact plug may have reduced contact area when there is misalignment so that it may be beneficial to increase contact area by shaping.

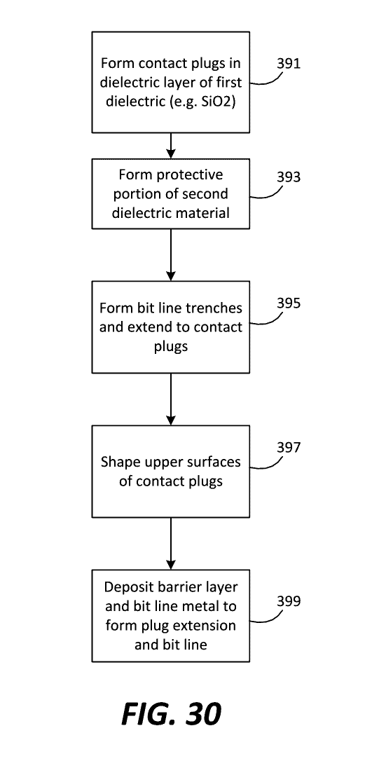

FIG. 30 illustrates steps in forming contact plugs and bit lines. Contact plugs are formed 391 in a dielectric layer such as silicon oxide, e.g. by CVD deposition of tungsten in contact holes. Protective portions of second dielectric material (e.g. silicon nitride) are formed 393 to later prevent current leakage between contact plugs and neighboring bit lines. Protective portions may be formed by etching back contact plugs to form plug-shaped recesses or spaces and then depositing second dielectric in recesses and etching back. Protective portions may be formed as a sheet of second dielectric prior to formation of contact holes in some cases. Subsequently, bit line trenches are formed 395 by etching. Etching continues to expose upper surfaces of contact plugs but is constrained by second dielectric so that etching maintains a minimum distance from neighboring contact plugs. Upper surfaces of contact plugs are then shaped 397 by continued etching using either the same etch conditions or different conditions to produce depressions (e.g. conical depressions) in upper surfaces of contact plugs. Subsequently, barrier layer and bit line metal materials are deposited 399 to form plug extensions and bit lines.

### CONCLUSION

Although the various aspects have been described with respect to examples, it will be understood that protection within the full scope of the appended claims is appropriate.

It is claimed:

1. An integrated circuit connection structure comprising:
a contact plug extending vertically in a first dielectric;
a conductive line formed of a metal extending horizontally in the first dielectric; and
a plug extension that extends between a top surface of the contact plug and the conductive line, the plug extension formed of the metal, the plug extension having a bottom surface that lies in contact with the top surface of the contact plug, the plug extension bounded on at least one side by a portion of a second dielectric material.

2. The integrated circuit connection structure of claim 1 wherein the top surface of the contact plug is partially in contact with the bottom surface of the plug extension and is partially covered by the second dielectric.

3. The integrated circuit connection structure of claim 1 wherein the top surface of the contact plug has a first perimeter, the bottom surface of the plug extension has a second perimeter, the second perimeter having a section that is coextensive with a corresponding section of the first perimeter.

4. The integrated circuit connection structure of claim 1 wherein the conductive line overlies the portion of the second dielectric in an area that lies adjacent to the extension plug.

5. The integrated circuit connection structure of claim 1 wherein the first dielectric is silicon oxide and the second dielectric is silicon nitride.

6. The integrated circuit connection structure of claim 5 wherein the second dielectric material forms a silicon nitride layer that extends between an underlying layer of silicon oxide and an overlying layer of silicon oxide.

7. The integrated circuit connection structure of claim 6 further comprising an adjacent conductive line that extends parallel to the conductive line, the adjacent conductive line having a bottom surface that lies along a top surface of the silicon nitride layer so that silicon nitride extends between the adjacent conductive line and the contact plug.

8. The integrated circuit connection structure of claim 1 wherein the portion of the second dielectric material forms a collar around the top surface of the contact plug.

9. The integrated circuit connection structure of claim 8 wherein the collar extends higher than the top surface of the contact plug and connects a bottom surface of the conductive line.

10. The integrated circuit connection structure of claim 1 wherein the portion of the second dielectric material occupies an area of the top surface of the contact plug that is not occupied by the plug extension.

11. The integrated circuit connection structure of claim 10 wherein the portion of the second dielectric material and the plug extension together occupy the entire area of the top surface of the contact plug.

12. The integrated circuit connection structure of claim 1 wherein the bottom surface of the plug extension lies in contact with the top surface of the contact plug along an interface that is substantially conical in shape.

13. The integrated circuit of claim 12 wherein the interface is substantially defined by an inverted conical surface that has a taper angle between thirty five degrees (35°) and fifty five degrees (55°).

14. A method of forming a connection structure comprising:
forming a contact plug;
forming a protective portion of a first dielectric material;
forming a layer of a second dielectric material over the contact plug;
forming an opening in the layer of the second dielectric material that exposes a portion of a top surface of the contact plug;
forming a metal plug extension in the opening, the metal plug extension laterally constrained in at least one direction by the protective portion of the first dielectric material; and
forming a plurality of conductive metal lines, a first conductive metal line formed over the metal plug extension and in electrical contact with the metal plug extension, a second conductive metal line adjacent to the first conductive metal line being separated from the contact plug by the protective portion of the first dielectric material.

15. The method of claim 14 wherein forming the opening in the layer of the second dielectric material includes performing anisotropic etching using an etch that is selective to the second dielectric material, having a significantly higher etch rate for the second dielectric material than for the first dielectric material.

16. The method of claim 14 further comprising, subsequent to exposing the portion of the top surface of the contact plug, etching the portion of the top surface of the contact plug to thereby form a substantially conical depression in the contact plug.

17. The method of claim 16 wherein the depression is subsequently filled by the metal plug extension so that an interface between the metal plug extension and the contact plug is substantially conical in shape with an angle between thirty five degrees (35°) and fifty five degrees (55°).

18. The method of claim 16 wherein forming the contact plug includes depositing tungsten (W) by Chemical Vapor Deposition (CVD) thereby forming a seam in a central area of the contact plug, and wherein the etching the portion of the top surface of the contact plug provides a higher etch rate along the seam than in a peripheral area of the top surface of the contact plug.

19. The method of claim 14 wherein the first dielectric material is silicon oxide and the second dielectric material is silicon oxide.

20. The method of claim 14 wherein the protective portion of the first dielectric material is formed by depositing a layer of the first dielectric material over a layer of the second dielectric material prior to formation of the contact plug, and wherein the contact plug is subsequently formed by etching a contact hole through the layer of the first dielectric material and the layer of the second dielectric material and filling the hole with metal.

21. The method of claim 20 further comprising etching back the contact plug prior to deposition of the second dielectric material so that the top surface of the contact plug lies lower than a top surface of the layer of the first dielectric material.

22. The method of claim 14 wherein the protective portion of the first dielectric material is formed by, subsequent to forming the opening in the layer of the second dielectric material:
selectively etching back the contact plug to form a plug-shaped space;
filling the plug-shaped space with the first dielectric material; and
subsequently, performing anisotropic selective etching to remove exposed first dielectric material from the opening, while leaving the protective portion of the first dielectric material in a portion of the plug-shaped space that is not exposed.

23. The method of claim 14 wherein the protective portion of the first dielectric material is formed by:
subsequent to forming the contact plug, etching back the contact plug;
subsequently, etching back dielectric around the contact plug, using isotropic etching, to form a recess around the top surface of the contact plug;
subsequently, depositing the first dielectric material; and
subsequently etching back the first dielectric material to expose at least a central portion of the top surface of the contact plug while leaving the first dielectric material in the recess.

24. The method of claim 23 wherein the protective portion forms a ring that encircles the top surface of the contact plug and partially overlies the top surface of the contact plug near a perimeter of the top surface of the contact plug.

25. A method of forming a connection structure comprising:
forming a contact plug;
subsequently recessing a top surface of the contact plug;
forming a protective portion of a first dielectric material in a recessed space adjacent to the top surface of the contact plug;
subsequently exposing a contact area of the recessed top surface of the contact plug using selective anisotropic etching; and
depositing metal to form a plurality of conductive lines, the metal lying in contact with the contact area of the recessed top surface of the contact plug under a first conductive line, a second conductive line separated from the contact plug by the protective portion of the first dielectric material.

26. The method of claim 25 further comprising, subsequent to recessing the top surface of the contact plug:
etching isotropically to form an annular recess about the top surface of the contact plug; and
forming the protective portion in the annular recess, the protective portion circumscribing the top surface of the contact plug and partially overlying the top surface of the contact plug.

27. The method of claim 25 wherein recessing the top surface of the contact plug leaves the recessed space having a plug-shape extending over the top surface of the contact plug, and further comprising:
filling the recessed space with the first dielectric to form a dielectric plug; and
subsequently etching away part of the dielectric plug overlying the contact area to thereby expose the contact area of the recessed top surface of the contact plug while a remaining part of the dielectric plug forms the protective portion on an unexposed area of the top surface of the contact plug.
